(19) United States
(12) Patent Application Publication
(10) Pub. No.: US 2016/0095214 A1
(43) Pub. Date: Mar. 31, 2016

(54) CERAMIC SUBSTRATE

(71) Applicant: NGK SPARK PLUG CO., LTD., Nagoya-shi (JP)

(72) Inventors: Ryouta FUKUI, Komaki-shi (JP); Kazushige AKITA, Nagoya-shi (JP)

(21) Appl. No.: 14/858,603

(22) Filed: Sep. 18, 2015

(30) Foreign Application Priority Data
Sep. 29, 2014 (JP) 2014-197841

(51) Int. Cl. H05K 1/03; H05K 1/09; H05K 1/11

(52) U.S. Cl. CPC H05K 1/0306; H05K 1/115; H05K 1/111; H05K 1/09

(57) ABSTRACT

A ceramic substrate includes: a plate-shaped substrate main body made of an insulating ceramic material; and a metallization layer primarily made of a conductive material, and formed over an entire perimeter of a surface of the substrate main body, along an outer edge of the surface. The ceramic substrate further includes: a composite material layer interposed between the substrate main body and the metallization layer, formed along the outer edge, and containing a ceramic material that is the same as the ceramic material of the substrate main body, and a conductive material that is the same as the conductive material of the metallization layer; and electrode pads primarily made of a conductive material, and formed at a position on the surface, inward of the metallization layer and the composite material layer, and spaced apart from the metallization layer and the composite material layer.

### CROSS REFERENCE TO RELATED APPLICATIONS

The present application claims priority to Japanese Patent Application No. 2014-197841, which was filed on Sep. 29, 2014, the disclosure of which is herein incorporated by referenced in its entirety.

### BACKGROUND OF THE INVENTION

1. Field of the Invention

The present invention relates to a ceramic substrate.

2. Description of Related Art

A structure of a ceramic substrate has been known in which electrode pads to be connected to an electronic component, and a metallization layer on which a sealing member for hermetically sealing the electronic component is to be mounted, are provided on a surface of a plate-shaped substrate main body made of an insulating ceramic material. Patent Document 1 discloses a structure in which a composite material layer containing an insulating ceramic material and a conductive material is formed over the entire surface of a substrate main body, and electrode pads and a metallization layer are formed on the composite material layer in order to prevent separation of the metallization layer from the substrate main body.

### RELATED ART DOCUMENT

Patent Document 1 is International Patent Publication No. 2013/137214.

### BRIEF SUMMARY OF THE INVENTION

In the technique disclosed in Patent Document 1, the electrode pads are raised due to the composite material layer, and thereby the position at which an electronic component is mounted is raised. Therefore, the size of a device obtained by mounting the electronic component and a sealing member on the ceramic substrate is increased.

The present invention has been made to solve the above problems and can be embodied in the following modes.

(1) According to one mode of the present invention, a ceramic substrate is provided which includes: a plate-shaped substrate main body made of an insulating ceramic material; and a metallization layer mainly (primarily) made of a conductive material, and formed over an entire perimeter of a surface of the substrate main body, along an outer edge of the surface. The ceramic substrate further includes: a composite material layer interposed between the substrate main body and the metallization layer, formed along the outer edge, and containing a ceramic material of the same kind as the ceramic material of the substrate main body, and a conductive material of the same kind as the conductive material of the metallization layer (i.e., containing a ceramic material that is the same as the ceramic material of the substrate made body, and a conductive material that is the same as the conductive material of the metallization layer); and electrode pads mainly (primarily) formed of a conductive material, and formed at a position on the surface, inward of the metallization layer and the composite material layer, and spaced apart from the metallization layer and the composite material layer. According to this mode, the electrode pads are formed at a position on the surface of the substrate main body, inward of the composite material layer and the metallization layer. Therefore, an increase in the size of a device due to the composite material layer can be avoided while preventing, by the composite material layer, separation of the metallization layer from the substrate main body. In addition, the composite material layer and the electrode pads are spaced apart from each other at a predetermined interval on the surface of the substrate main body. Therefore, short-circuit between the metallization layer and the electrode pads through the composite material layer can be avoided.

(2) The ceramic substrate of the above mode may further include a conductor via mainly made of a conductive material, penetrating at least one ceramic layer constituting the substrate main body, and being in contact with the metallization layer. In other words, in some embodiments of the ceramic substrate, the substrate main body includes at least one ceramic layer, and the ceramic substrate further comprises a conductor via primarily formed of a conductive material, the conductive via penetrating the at least one ceramic layer of the substrate main body, and being in contact with the metallization layer. According to this mode, when a plating layer is formed on the metallization layer, a current can be applied to the metallization layer through the conductor via. Therefore, the quality of the plating layer formed on the metallization layer can be improved as compared to a case where a current is applied to the metallization layer through the composite material layer.

(3) In the ceramic substrate of the above mode, the composite material layer may be formed over the entire perimeter of the surface. According to this mode, separation of the metallization layer from the substrate main body can be avoided over the entire perimeter of the metallization layer.

(4) In the ceramic substrate of the above mode, the metallization layer may be formed over the top of the composite material layer, extending onto the surface inward of the composite material layer. According to this mode, the composite material layer on which a plating layer is less likely to be formed as compared to the metallization layer is covered with the metallization layer. Therefore, the quality of the plating layer formed inward of the metallization layer is improved as compared to the case where the surface on the inner side of the composite material layer is exposed under the metallization layer.

The present invention can be embodied in various forms other than a ceramic substrate, for example, in the form of a device equipped with a ceramic substrate, or a device for manufacturing a ceramic substrate, or a method for manufacturing a ceramic substrate.

### BRIEF DESCRIPTION OF THE DRAWINGS

Illustrative aspects of the invention will be described in detail with reference to the following figures wherein:

FIG. 1 is an explanatory view illustrating an upper surface of a ceramic substrate.

FIG. 2 is an explanatory view illustrating a cross-section of the ceramic substrate.

FIG. 3 is an explanatory view illustrating a device in which an electronic component is mounted on a ceramic substrate.

FIG. 4 is a flow chart illustrating processes in a ceramic substrate manufacturing method.

FIG. 5 is an explanatory view illustrating an upper surface of a ceramic substrate according to a second embodiment.

FIG. 6 is an explanatory view illustrating a cross-section of the ceramic substrate.

FIG. 7 is an explanatory view illustrating a cross-section of the ceramic substrate.

### DETAILED DESCRIPTION OF EXEMPLARY EMBODIMENTS OF THE INVENTION

### A. First Embodiment

A-1. Structure of Ceramic Substrate

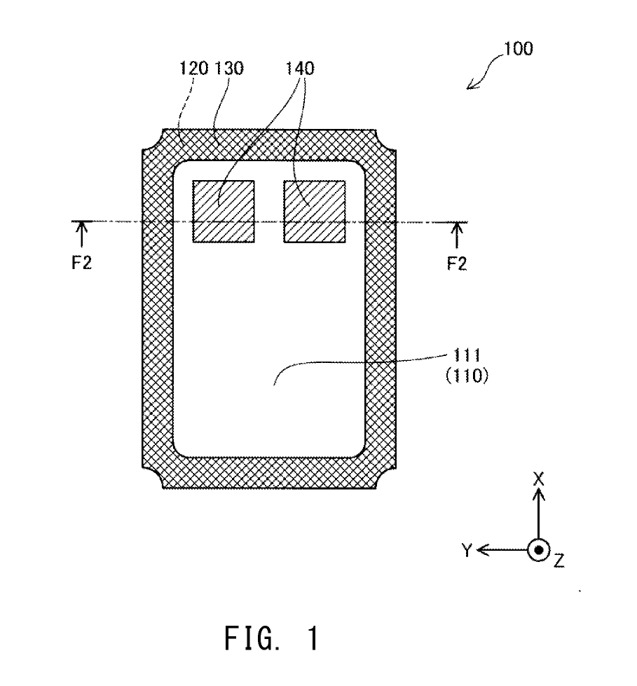

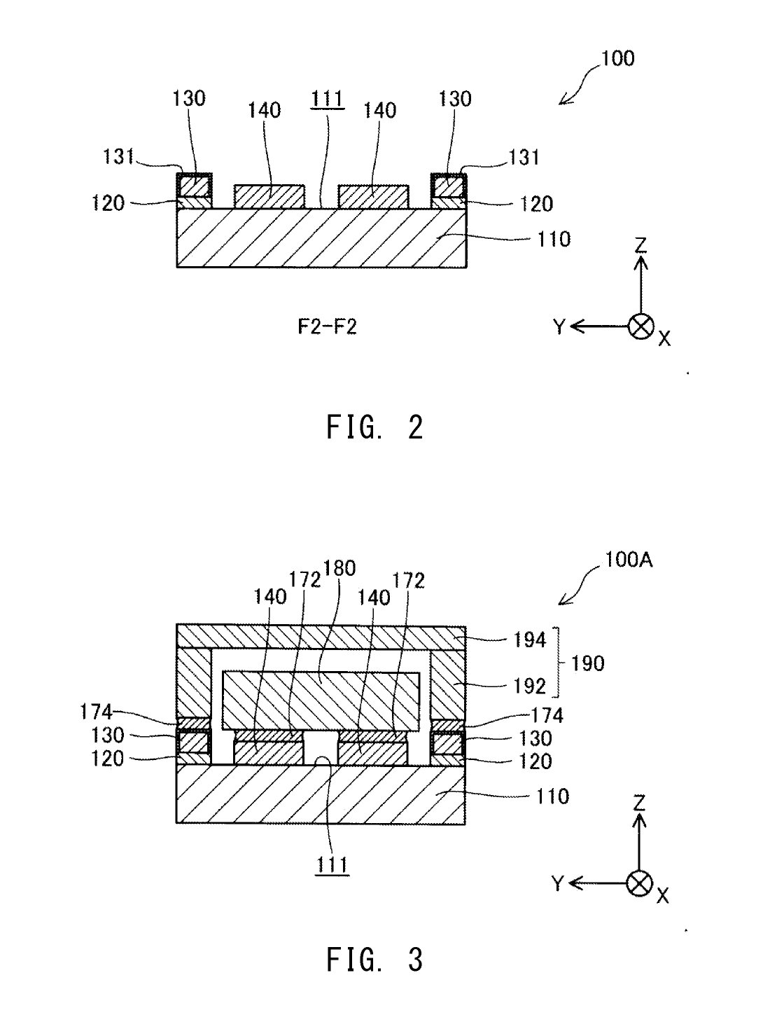

FIG. 1 is an explanatory view illustrating an upper surface of a ceramic substrate 100. FIG. 2 is an explanatory view illustrating a cross-section of the ceramic substrate 100. FIG. 2 illustrates the cross-section of the ceramic substrate 100 as viewed from the direction of arrows F2-F2 in FIG. 1. In FIGS. 1 and 2, X, Y and Z axes orthogonal to each other are shown. Among the X, Y and Z axes shown in FIGS. 1 and 2, the X axis is an axis extending from the near side (−X axis side) of the drawing sheet of FIG. 2 toward the far side (+X axis side) of the drawing sheet, the Y axis is an axis extending from the right side (−Y axis side) of the drawing sheet of FIG. 2 toward the left side (+Y axis side) of the drawing sheet, and the Z axis is an axis extending from the lower side (−Z axis side) of the drawing sheet of FIG. 2 toward the upper side (+Z axis side) of the drawing sheet. The X, Y and Z axes shown in FIGS. 1 and 2 correspond to X, Y and Z axes shown in other figures.

The ceramic substrate 100 constitutes at least a part of a circuit that realizes a predetermined function. In the present embodiment, the ceramic substrate 100 constitutes a part of a surface acoustic wave (SAW) duplexer. The ceramic substrate 100 includes a substrate main body 110, a composite material layer 120, a metallization layer 130, and electrode pads 140.

The substrate main body 110 of the ceramic substrate 100 is a plate-shaped substrate made of an insulating ceramic material. In the present embodiment, the substrate main body 110 has a multilayer structure in which a plurality of ceramic layers are built up in the Z axis direction. In the present embodiment, the substrate main body 110 includes conductor layers (not shown) formed between the adjacent ceramic layers, and a conductor via (not shown) formed so as to penetrate the ceramic layers.

In the present embodiment, the substrate main body 110 is formed by sintering a material obtained by mixing powder of borosilicate-based glass and powder of alumina (Al₂O₃), and the insulating ceramic constituting the substrate main body 110 contains borosilicate-based glass and alumina as principal components. The borosilicate-based glass contains silicon dioxide (SiO₂), alumina (Al₂O₃), and boron oxide (B₂O₃) as principal components.

The metallization layer 130 of the ceramic substrate 100 is a layer primarily (mainly) made of a conductive material. In the present embodiment, the metallization layer 130 primarily made of a conductive material means a metallization layer containing 50% by volume or more of a conductive material. The metallization layer 130 is formed along an outer edge of a surface 111, facing in the +Z axis direction (i.e., an upper surface), of the substrate main body 110, over the entire perimeter of the surface 111. In FIG. 1, the metallization layer 130 is shown by hatching declined to the left.

In the present embodiment, a principal component of the metallization layer 130 is tungsten (W). In the present embodiment, a plating layer 131 is formed on the surface of the metallization layer 130. In the present embodiment, a principal component of the plating layer 131 is nickel (Ni). In another embodiment, a principal component of the plating layer 131 may be at least one of gold (Au) and palladium (Pd).

The composite material layer 120 of the ceramic substrate 100 is a layer containing ceramic materials of the same kind as those of the substrate main body 110, and a conductive material of the same kind as that of the metallization layer 130. In the present embodiment, the composite material layer 120 contains borosilicate-based glass and alumina as the ceramic materials of the same kind as those of the substrate main body 110, and contains tungsten (W) as the conductive material of the same kind as that of the metallization layer 130.

The composite material layer 120 is formed along the outer edge of the surface 111, facing in the +Z axis direction (i.e., the upper surface), of the substrate main body 110. The composite material layer 120 is interposed between the substrate main body 110 and the metallization layer 130. In FIG. 1, the composite material layer 120 is shown by hatching declined to the right. In the present embodiment, the shape of the composite material layer 120, as viewed in the Z axis direction (i.e., a top view), is the same as the shape of the metallization layer 130. In the present embodiment, the composite material layer 120 is formed over the entire perimeter of the surface 111. In another embodiment, the composite material layer 120 may be partially formed between the substrate main body 110 and the metallization layer 130.

The electrode pads 140 of the ceramic substrate 100 are layers primarily (mainly) made of a conductive material. In the present embodiment, the electrode pads 140 primarily made of a conductive material mean electrode pads containing 50% by volume or more of a conductive material. The electrode pads 140 are formed at a position on the surface 111, inward of the metallization layer 130 and the composite material layer 120, and spaced apart from the metallization layer 130 and the composite material layer 120. In FIG. 1, the electrode pads 140 are shown by hatching declined to the left. No composite material layer 120 is formed between the substrate main body 110 and the electrode pad 140. A plating layer may be formed on the surface of the electrode pad 140, in like manner to the metallization layer 130.

FIG. 3 is an explanatory view illustrating a device 100A in which an electronic component is mounted on the ceramic substrate 100. The device 100A includes an electronic component 180 and a sealing member 190.

The electronic component 180 of the device 100A, as well as the substrate main body 110, constitute a circuit. The electronic component 180 is bonded to the electrode pads 140 via a solder 172. In the present embodiment, the solder 172 is primarily (mainly) formed of tin (Sn)-silver (Ag).

The sealing member 190 of the device 100A hermetically seals the electronic component 180 mounted on the substrate main body 110. The sealing member 190 is bonded to the metallization layer 130 via a brazing material 174. In the present embodiment, the brazing material 174 is primarily (mainly) made of silver (Ag). In the present embodiment, the sealing member 190 includes a metal ring part 192 and a metal lid part 194. The ring part 192 of the sealing member 190, as viewed in the Z axis direction (i.e., a top view), has an annular shape similar to the shape of the metallization layer 130. The lid part 194 of the sealing member 190, as viewed in the Z axis direction (i.e., a top view), has a plate shape similar to the shape of the substrate main body 110. The lid part 194 is welded to a +Z-axis-side (i.e., an upper side) of the ring part 192.

A-2. Method for Manufacturing Ceramic Substrate

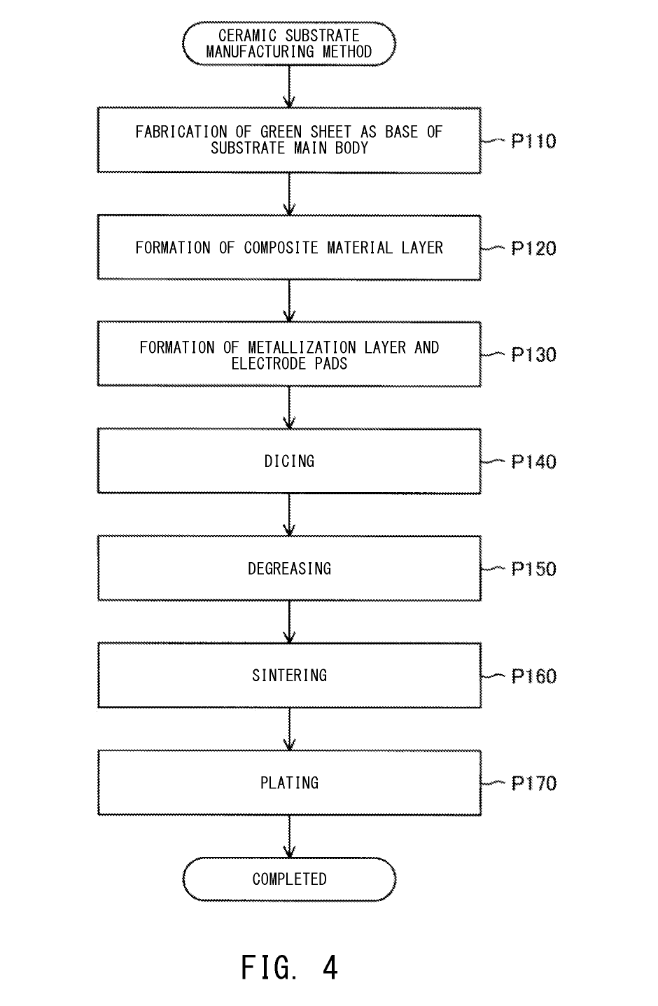

FIG. 4 illustrates processes in a method for manufacturing the ceramic substrate 100. When manufacturing the ceramic substrate 100, first, a manufacturer fabricates a green sheet as a base of the substrate main body 110 (process P110). The green sheet is obtained by mixing a binder, a plasticizer, a solvent, and the like with raw material powder of an insulating ceramic, and forming the mixture into a thin-plate (sheet) shape. In the present embodiment, the raw material of the green sheet includes powder of borosilicate-based glass and powder of alumina. The borosilicate-based glass as the raw material contains silicon dioxide (SiO₂), alumina (Al₂O₃), and boron oxide (B₂O₃) as principal components.

In the present embodiment, the manufacturer weighs the powder of borosilicate-based glass and the powder of alumina as raw materials, and then puts the raw materials into an alumina container (pot). Thereafter, the manufacturer adds acrylic resin as a binder, an appropriate amount of methylethylketone (MEK) as a solvent, and an appropriate amount of dioctylphthalate (DOP) as a plasticizer, to the raw materials in the pot. Thereafter, the manufacturer mixes the raw material in the pot to obtain a ceramic slurry. Thereafter, the manufacturer fabricates a green sheet from the ceramic slurry in a doctor blade process. In the present embodiment, the manufacturer fabricates a plurality of substrate main bodies 110 from a single green sheet. In the present embodiment, the manufacturer forms conductor layers and conductor vias on the green sheet by use of a conductive paste.

After formation of the green sheet (process P110), the manufacturer forms the composite material layer 120 on the green sheet (process P120). In the present embodiment, the manufacturer forms a plurality of composite material layers 120 on the single green sheet by printing a paste on the green sheet by screen printing. The paste used for the composite material layers 120 is obtained by mixing a binder, a plasticizer, a solvent, and the like with ceramic materials of the same kind as those of the substrate main body 110 and a conductive material of the same kind as that of the metallization layer 130. In the present embodiment, the raw material of the composite material layer 120 contains borosilicate-based glass and alumina as the ceramic materials of the same kind as those of the substrate main body 110, and contains tungsten (W) as the conductive material of the same kind as that of the metallization layer 130. In the present embodiment, the manufacturer adds ethylcellulose as the binder and terpineol as the solvent to powder of borosilicate-based glass, powder of alumina, and powder of tungsten (W), and thereafter, kneads the mixture by use of a three-roll mill, thereby to obtain the paste for the composite material layers 120.

After formation of the composite material layers 120 (process P120), the manufacturer forms the metallization layer 130 and the electrode pads 140 (process P130). In the present embodiment, the manufacturer forms a plurality of metallization layers 130 and a plurality of electrode pads 140 on the single green sheet by printing a paste on the green sheet by screen printing. The paste used for the metallization layers 130 and the electrode pads 140 is obtained by mixing a binder, a plasticizer, a solvent, and the like with powder of a conductive material. In the present embodiment, the raw material of the metallization layers 130 and the electrode pads 140 is powder of tungsten (W). In the present embodiment, the manufacturer adds ethylcellulose as the binder and terpineol as the solvent to the powder of tungsten (W), and thereafter, kneads the mixture by use of a three-roll mill, thereby to obtain the paste for the metallization layers 130 and the electrode pads 140.

After formation of the metallization layers 130 and the electrode pads 140 (process P130), the manufacturer performs dicing (process P140). In the dicing process, the manufacturer cuts and divides the single green sheet into a plurality of ceramic substrates 100.

After the dicing (process P140), the manufacturer degreases each ceramic substrate 100 (process P150). In the present embodiment, the manufacturer degreases the ceramic substrate 100 by causing the ceramic substrate 100 to be exposed to the air at 250° C. for 10 hours.

After the decreasing of the ceramic substrate 100 (process P150), the manufacturer sinters the ceramic substrate 100 (process P160). In the present embodiment, the manufacturer sinters the ceramic substrate 100 by causing the ceramic substrate 100 to be exposed to a reducing gas at 850° C. for 30 minutes.

After the sintering of the ceramic substrate 100 (process P160), the manufacturer performs electroplating on the metallization layer 130 (process P170). In the present embodiment, the manufacturer performs nickel (Ni) electroplating on the metallization layer 130. In the present embodiment, the manufacturer performs electroplating also on the electrode pads 140 as well as on the metallization layer 130. Through these processes, the ceramic substrate 100 is completed.

A-3. Effects

According to the above-described first embodiment, the electrode pads 140 are formed at a position on the surface 111 of the substrate main body 110, inward of the metallization layer 130 and the composite material layer 120, and spaced apart from the metallization layer 130 and the composite material layer 120. Therefore, an increase in the device size due to the composite material layer 120 can be avoided while preventing, by the composite material layer 120, separation of the metallization layer 130 from the substrate main body 110. Further, the composite material layer 120 and the electrode pads 140 are spaced apart from each other at a predetermined interval on the surface 111 of the substrate main body 110. Therefore, short-circuit between the metallization layer 130 and the electrode pads 140 via the composite material layer 120 can be avoided. Further, the composite material layer 120 is formed over the entire perimeter of the surface 111. Therefore, separation of the metallization layer 130 from the substrate main body 110 can be prevented over the entire perimeter of the metallization layer 130.

### B. Second Embodiment

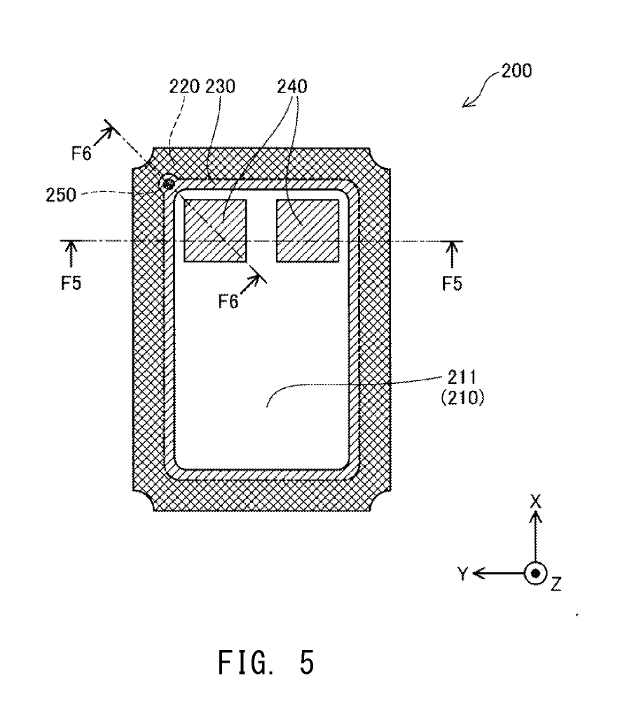

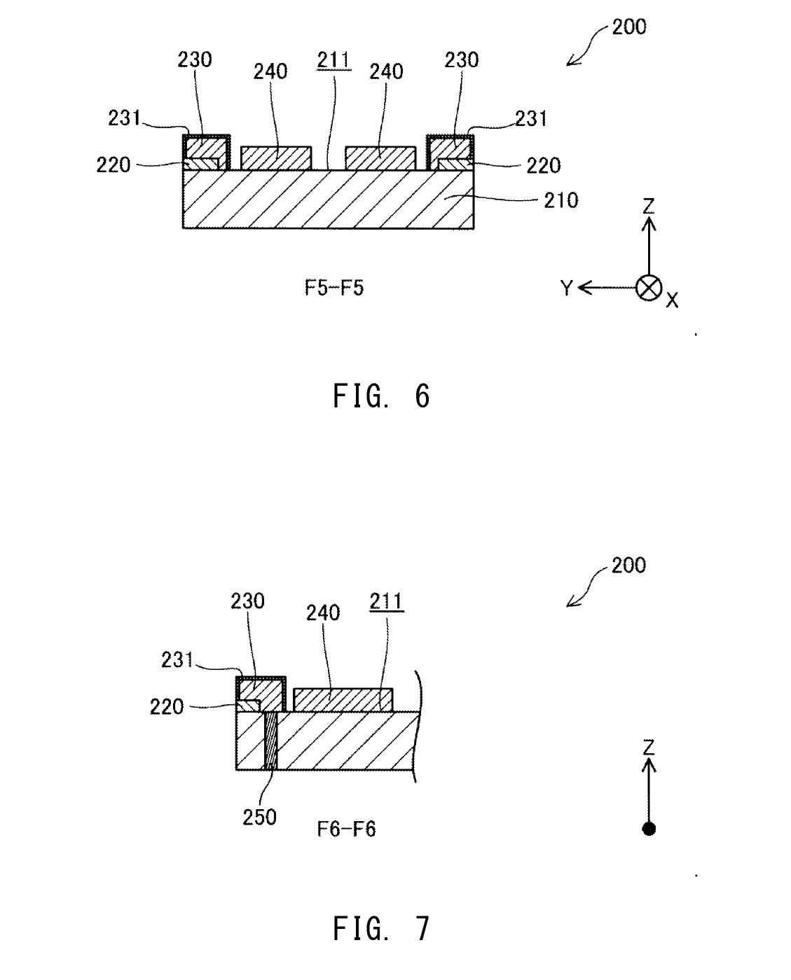

FIG. 5 is an explanatory view illustrating an upper surface of a ceramic substrate 200 according to a second embodiment. FIG. 7 is an explanatory view illustrating a cross-section of the ceramic substrate 200. FIG. 7 illustrates the cross-section of the ceramic substrate 200 as viewed from the direction of arrows F6-F6 in FIG. 5. In FIGS. 5 and 6, X, Y and Z axes are shown as in FIGS. 1 and 2.

The ceramic substrate 200 of the second embodiment is identical to the ceramic substrate 100 of the first embodiment except the structures of the substrate main body and the metallization layer. The ceramic substrate 200 includes a substrate main body 210, a composite material layer 220, a metallization layer 230, and electrode pads 240.

The substrate main body 210 of the ceramic substrate 200 is identical to the substrate main body 110 of the first embodiment except that a conductor via 250 in contact with the metallization layer 230 is provided. The conductor via 250 is a conductor primarily (mainly) made of a conductive material. The conductor via 250 penetrates the substrate main body 110. In the present embodiment, the conductor via 250 primarily made of a conductive material means a conductor via containing 50% by volume or more of a conductive material.

The composite material layer 220 of the ceramic substrate 200 is identical to the composite material layer 120 of the first embodiment except that it is formed on a surface 211, facing in the +Z axis direction (i.e., an upper surface), of the substrate main body 210. In FIG. 5, the composite material layer 220 is shown by hatching declined to the right. In the present embodiment, the composite material layer 220 is formed so as not to cover the conductor via 250.

The metallization layer 230 of the ceramic substrate 200 is identical to the metallization layer 130 of the first embodiment except that it is formed over the top of the composite material layer 220, extending to the surface 211 of the substrate main body 210 inward of the composite material layer 220, and that it is in contact with the conductor via 250. In the present embodiment, as in the first embodiment, a plating layer 231 is formed on the surface of the metallization layer 230.

The electrode pads 240 of the ceramic substrate 200 are identical to the electrode pads 140 of the first embodiment except that they are formed on the surface 211 of the substrate main body 210.

According to the above-described second embodiment, as in the first embodiment, an increase in the device size due to the composite material layer 220 can be avoided while preventing, by the composite material layer 220, separation of the metallization layer 230 from the substrate main body 210. Further, when the plating layer 231 is formed on the metallization layer 230, a current can be applied to the metallization layer 230 through the conductor via 250. Therefore, the quality of the plating layer 231 formed on the metallization layer 230 can be improved as compared to the case where a current is applied to the metallization layer 230 through the composite material layer 220. Further, the composite material layer 220 on which a plating layer is less likely to be formed as compared to the metallization layer 230 is covered with the metallization layer 230. Therefore, the quality of the plating layer 231 formed inward of the metallization layer 230 can be improved as compared to the case where the surface on the inner side of the composite material layer 220 is exposed under the metallization layer 230.

### C. Other Embodiments

The present invention is not limited to the above modes, embodiments and modifications/variations and can be embodied in various forms without departing from the scope of the present invention. For example, it is feasible to appropriately replace or combine any of the technical features of the modes of the present invention described in “Summary of the Invention” and the technical features of the embodiments and modifications/variations of the present invention in order to solve part or all of the above-mentioned problems or achieve part or all of the above-mentioned effects. Any of these technical features, if not explained as essential in the present specification, may be deleted as appropriate.

The insulating ceramic of the substrate main body 110 (210) is not limited to a ceramic containing borosilicate-based glass and alumina as principal components, and may be a ceramic containing borosilicate-based glass and mullite as principal components, or a ceramic containing borosilicate-based glass and cordierite powder as principal components, or a ceramic containing alumina or silicon nitride as a principal component. The glass component of the substrate main body 110 (210) is not limited to borosilicate-based glass, and may be crystallized glass.

The conductive material used for the metallization layer 130 (230) is not limited to tungsten (W), and may be molybdenum (Mo), or an alloy containing at least one of tungsten (W) and molybdenum (Mo) as a principal component.

The conductor via 250 in contact with the metallization layer 230 is not necessarily formed to penetrate the substrate main body 210, and may be formed to penetrate at least one ceramic layer constituting the substrate main body 210.

### DESCRIPTION OF REFERENCE NUMERALS

100: ceramic substrate
100A: device
110: substrate main body
111: surface
120: composite material layer
130: metallization layer
131: plating layer
140: electrode pad
172: solder
174: brazing material
180: electronic component
190: sealing member
192: ring part
194: lid part
200: ceramic substrate
210: substrate main body
211: surface
220: composite material layer
230: metallization layer
231: plating layer
240: electrode pad
250: conductor via

What is claimed is:

1. A ceramic substrate comprising:
a substrate main body made of an insulating ceramic material, having a plate-like shape, and including a surface having a perimeter and an outer edge; and
a metallization layer primarily made of a conductive material, and formed over the entire perimeter of the surface of the substrate main body, along the outer edge of the surface;
a composite material layer interposed between the substrate main body and the metallization layer, formed along the outer edge of the surface, and containing a ceramic material that is the same as the ceramic material of the substrate main body, and a conductive material that is the same as the conductive material of the metallization layer; and
electrode pads primarily made of a conductive material, each electrode pad formed at a position on the surface inward of the metallization layer and the composite material layer, and spaced apart from the metallization layer and the composite material layer.

2. The ceramic substrate according to claim 1 wherein the substrate main body includes at least one ceramic layer, and
wherein the ceramic substrate further comprises a conductor via primarily formed of a conductive material, the conductor via penetrating the at least one ceramic layer of the substrate main body, and being in contact with the metallization layer.

3. The ceramic substrate according to claim 1, wherein the composite material layer is formed over the entire perimeter of the surface.

4. The ceramic substrate according to claim 1, wherein the metallization layer is formed over a top of the composite material layer, extending onto the surface of the substrate main body inward of the composite material layer.

5. The ceramic substrate according to claim 2, wherein the composite material layer is formed over the entire perimeter of the surface.

6. The ceramic substrate according to claim 2, wherein the metallization layer is formed over a top of the composite material layer, extending onto the surface of the substrate main body inward of the composite material layer.

7. The ceramic substrate according to claim 3, wherein the metallization layer is formed over a top of the composite material layer, extending onto the surface of the substrate main body inward of the composite material layer.

8. The ceramic substrate according to claim 5, wherein the metallization layer is formed over a top of the composite material layer, extending onto the surface of the substrate main body inward of the composite material layer.
